(19) United States
(12) Patent Application Publication
(10) Pub. No.: US 2024/0376014 A1
(43) Pub. Date: Nov. 14, 2024

(54) CERAMIC

(71) Applicant: Murata Manufacturing Co., Ltd., Nagaokakyo-shi (JP)

(72) Inventor: Sakyo HIROSE, Nagaokakyo-shi (JP)

(21) Appl. No.: 18/780,844

(22) Filed: Jul. 23, 2024

Related U.S. Application Data
(63) Continuation of application No. PCT/JP2023/012374, filed on Mar. 28, 2023.

(30) Foreign Application Priority Data
Mar. 31, 2022 (JP) 2022-059889

(51) Int. Cl. C04B 35/497; H10N 15/10

(52) U.S. Cl. CPC C04B 35/497; H10N 15/15; C04B 2235/3206; C04B 2235/3224; C04B 2235/3253; C04B 2235/3258; C04B 2235/3296; C04B 2235/768; C04B 2235/9607

(57) ABSTRACT

A ceramic represented by: (1-m)PbSc_{0.5-x}Ta_{0.5+x}O₃-mPbMg_{0.5-y}W_{0.5+y}O₃, wherein, 0.03≤m≤0.60; x, y≤0.1 and 0≤x+y≤0.13 when 0≤x, y; −0.1≤x<0 and 0≤y≤0.1 when 0>x and 0≤y; −0.1≤x, y and −0.13≤x+y<0 when 0≥x and 0>y; and 0<x≤0.1 and −0.1≤y<0 when 0<x and 0>y.

### CROSS REFERENCE TO RELATED APPLICATIONS

The present application is a continuation of International application No. PCT/JP2023/012374, filed Mar. 28, 2023, which claims priority to Japanese Patent Application No. 2022-059889, filed Mar. 31, 2022, the entire contents of each of which are incorporated herein by reference.

### TECHNICAL FIELD

The present disclosure relates to a ceramic.

### BACKGROUND ART

In recent years, as cooling elements, new solid cooling elements and cooling systems in which an electrocaloric effect is used have attracted attention, and research and development thereof have been actively conducted. The cooling systems have, as compared with existing cooling systems in which a refrigerant as a greenhouse gas is used, the advantages of high efficiency and low power consumption without requiring any refrigerant, and also have the advantage of being quiet because no compressor is used. In order to obtain an excellent electrocaloric effect, it is necessary to be a ferroelectric that exhibits a primary phase transition in a desired temperature range and allows the application of a large electric field. PbSc_{0.5}Ta_{0.5}O₃ (hereinafter, a ceramic containing Pb, Sc, and Ta is referred to also as “PST”) is known as the most promising material. For example, Non-Patent Documents 1 to 3 report that PbSc_{0.5}Ta_{0.5}O₃ exhibits a great electrocaloric effect.
Patent Document 1: WO 2021/131142 A
Non-Patent Document 1: Nature volume 575, pages 468-472 (2019)
Non-Patent Document 2: Ferroelectrics, 184, 239 (1996)
Non-Patent Document 3: J. Am. Ceram. Soc, 78 [71] 1947-52 (1995)

### SUMMARY OF THE DISCLOSURE

The solid cooling elements are required to exhibit great electrocaloric effects at temperatures depending on intended uses of the elements. For example, in the case of using the solid cooling elements for a refrigerator or the like, the elements may be required to exhibit electrocaloric effects at 4° C. or lower.

Conventional PSTs, however, exhibit great electrocaloric effects at 20° C. or higher, but the electrocaloric effects are significantly decreased at low temperatures, and the PSTs have problems with use at low temperatures as solid cooling elements.

The improved withstand voltages of the PSTs allows high voltages to be applied, thereby improving the electrocaloric effects. In addition, as the degrees of order of Sc and Ta, which are cations at the B sites of PSTs, are higher, more excellent ferroelectric characteristics are obtained, and the electrocaloric effects can be improved. PSTs with some of Pb substituted with Na allow high voltages to be applied with the withstand voltages improved, also allows the ferroelectric transition temperatures to be controlled to 20° C. or lower, and in addition, allows the degrees of order at the B sites to be easily increased, thus improving the electrocaloric effects at low temperatures, but the effects are limited, and further improvements are desired.

An object of the present disclosure is to provide a ceramic that exhibits a greater electrocaloric effect at a lower temperature than before.

The present disclosure relates to a ceramic represented by the formula (1):

(1-m)PbSc_{0.5-x}Ta_{0.5+x}O₃-mPbMg_{0.5-y}W_{0.5+y}O₃ (1)

wherein, in the formula (1):
0.03≤m≤0.60,
x, y≤0.1 and 0≤x+y≤0.13 when 0≤x, y,
−0.1≤x<0 and 0≤y≤0.1 when 0>x and 0≤y,
−0.1≤x, y and −0.13≤x+y<0 when 0≥x and 0>y, and
0<x≤0.1 and −0.1≤y<0 when 0<x and 0>y.

The present disclosure includes the following aspects.

[1] A ceramic represented by the formula (1):

(1-m)PbSc_{0.5-x}Ta_{0.5+x}O₃-mPbMg_{0.5-y}W_{0.5+y}O₃ (1)
wherein, in the formula (1),
0.03≤m≤0.60,
x, y≤0.1 and 0≤x+y≤0.13 when 0≤x, y,
when 0>x and 0≤y, −0.1≤x<0 and 0≤y≤0.1 when 0>x and 0≤y,
−0.1≤x, y and −0.13≤x+y<0 when 0≥x and 0>y, and
0<x≤0.1 and −0.1≤y<0 when 0<x and 0>y.

[2] The ceramic according to [1] mentioned above, where in the formula,
0≤x+y≤0.1 when 0≤x, y, and
−0.1≤x+y<0 when 0≥x and 0>y.

[3] The ceramic according to [1] or [2] mentioned above, where x is 0, and y is 0.

[4] The ceramic according to any of [1] to [3] mentioned above, where 0.05≤m≤0.5.

[5] The ceramic according to any of [1] to [4] mentioned above, where the crystal structure of the ceramic has a perovskite structure.

[6] An electrocaloric effect element, where a noble metal electrode and the ceramic according to any one of [1] to [5] mentioned above are alternately stacked.

[7] The electrocaloric effect element according to [6] mentioned above, where the noble metal electrode comprises Pt.

[8] An electronic component including the electrocaloric effect element according to [6] or [7] mentioned above.

[9] An electronic device including the electrocaloric effect element according to [6] or [7] mentioned above or the electronic component according to [8] mentioned above.

The present disclosure can provide a ceramic that exhibits a great electrocaloric effect at a low temperature. More specifically, the present disclosure can provide a ceramic that exhibits a great electrocaloric effect also at 0° C. or lower.

### BRIEF EXPLANATION OF THE DRAWINGS

FIG. 1 is a schematic sectional view of an electrocaloric effect element according to an embodiment of the present disclosure.

FIG. 2 is a diagram for explaining a measurement sequence for an electrocaloric effect.

FIG. 3 is a diagram showing measurement results of electrocaloric effects of samples of sample numbers 1 and 6 in an example.

FIG. 4 is a diagram showing results of a characteristic test for various compositions of x and y.

### DESCRIPTION OF THE PREFERRED EMBODIMENTS

Hereinafter, a ceramic according to the present disclosure and an electrocaloric effect element obtained with the use of the ceramic will be described in detail with reference to the drawings. However, the shapes and arrangements of the electrocaloric effect element and respective constituent elements according to the present embodiment are not limited to those in the illustrated examples.

### [Ceramic]

The ceramic according to an embodiment of the present disclosure contains Pb, Sc, Ta, Mg, and W as main components. The ceramic is a composite oxide containing Pb, Sc, Ta, Mg, and W, where a content ratio of Pb is substantially equal to a total content ratio of Sc, Ta, Mg, and W. When a content ratio of Sc is “0.5−x”, a content ratio of Ta is “0.5+x”, and when a content ratio of Mg is “0.5−y”, a content ratio of W is “0.5+y.”

As for the ranges of x and y:
x, y≤0.1 and 0≤x+y≤0.13 when 0≤x, y,
−0.1≤x<0 and 0≤y≤0.1 when 0>x and 0≤y,
−0.1≤x, y and −0.13≤x+y<0 when 0≥x and 0>y, and
0<x≤0.1 and −0.1≤y<0 when 0<x and 0>y.

When a total content ratio of Mg and W is denoted by “m”, a total content ratio of Sc and Ta is “1-m”, and the range of m is 0.03≤m≤0.60. It is to be noted that the ratios mentioned above are all molar ratios. The composition in the ranges mentioned above allows a great electrocaloric effect at a low temperature to be obtained.

Further, the feature that “the content ratio of Pb is substantially equal to the total content ratio of Sc, Ta, Mg, and W” is not limited to the case where the content ratio of Pb is exactly equal to the total content ratio of Sc, Ta, Mg, and W. More specifically, the feature that “the content ratio of Pb is substantially equal to the total content ratio of Sc, Ta, Mg, and W.” includes a case where the difference between the content ratio of Pb and the total content ratio of Sc, Ta, Mg, and W is, for example, within 3% in terms of molar ratio.

The composition of the ceramic according to the present disclosure can be analyzed and measured by performing composition analysis with the use of, for example, high-frequency inductively coupled plasma optical emission spectroscopy, X-ray fluorescence spectroscopy, or another method.

The electrocaloric effect is an endothermic and exothermic phenomenon caused by a change in entropy, produced when electric dipole moments in a substance are aligned or disordered by a change in an electric field. The performance index of the electrocaloric effect in the present disclosure may be an adiabatic temperature change (ΔT). More specifically, the fact that “the electrocaloric effect is great” may mean that the adiabatic temperature change (ΔT) is large. In the present disclosure, the adiabatic temperature change (ΔT) is preferably larger.

The adiabatic temperature change (ΔT) means a change in the temperature of the ceramic, caused by applying an electric field to the ceramic and/or removing the electric field applied to the ceramic. Specifically, the adiabatic temperature change (ΔT) may be the difference between the temperature of the ceramic before applying the electric field and the temperature of the ceramic immediately after applying the electric field, or may be the difference between the temperature of the ceramic before removing the electric field and the temperature of the ceramic immediately after removing the electric field.

The adiabatic temperature change ΔT is increased as the electric field strength applied to the ceramic is increased. In addition, the adiabatic temperature change ΔT is increased as the temperature of the ceramic with the electric field applied is closer to the ferroelectric transition temperature (hereinafter, referred to also as “phase transition temperature”). For example, the electrocaloric effect is rapidly reduced as the temperature of the ceramic becomes lower than the transition temperature. Specifically, a conventional PST with a transition temperature of about 15 to 25° C. has an electrocaloric effect significantly reduced at the ceramic temperature of 0° C. or lower.

In another aspect, the ceramic mentioned above may be a ceramic represented by formula (1):

(1-m)PbSc_{0.5-x}Ta_{0.5+x}O₃-mPbMg_{0.5-y}W_{0.5+y}O₃ (1)

In the formula (1):
0.03≤m≤0.60,
x, y≤0.1 and 0≤x+y≤0.13 when 0≤x, y,
−0.1≤x<0 and 0≤y≤0.1 when 0>x and 0≤y,
−0.1≤x, y and −0.13≤x+y<0 when 0≥x and 0>y, and
0<x≤0.1 and −0.1≤y<0 when 0<x and 0>y. x, y, and m fall within the ranges mentioned above, thereby allowing a great electrocaloric effect (for example, ΔT of 1.5 K or more when applying the electric field strength of 15 MV/m) at a low temperature to be obtained.

Although the present disclosure is not bound by any theory, a mechanism for obtaining such an effect mentioned above is considered as follows.

For example, adding Na or a paraelectric substance (for example, SrTiO₃) to a PST allows the phase transition temperature to be lowered, and the electrocaloric effect can be obtained also at 0° C. or lower. However, at the same time, the ferroelectricity is decreased, and thus, there is room for improvement in electrocaloric effect obtained. In the present disclosure, attention has been paid to PbMg_{0.5}W_{0.5}O₃ (hereinafter, a ceramic containing Pb, Mn, and W is referred to also as a “PMW”) that has a perovskite structure similarly to a PST and has the feature that cations at B sites are ordered, and it has been found that a more excellent electrocaloric effect can be obtained also at 0° C. or lower by adding such a PMW to a PST.

PbMg_{0.5}W_{0.5}O₃, which is an antiferroelectric, has the feature of being transferred to a ferroelectric by applying a voltage that is equal to or higher than the threshold voltage. In general, it is known that as the difference in ionic radius between two cations at the B sites is increased, the cations are more easily aligned, and the PMW has B sites likely to be aligned as compared with the PST. Since the ferroelectricity is significantly affected by the degree of alignment at the B sites, adding the PMW in which the B sites are likely to be aligned to the PST is considered to allow the ferroelectric transition temperature to be lowered without significantly decreasing the ferroelectricity, and as a result, produce an excellent electrocaloric effect at 0° C. or lower.

In the production of the PST, firing at a high temperature of 1400° C. has been necessary, and in addition, a long-time heat treatment at a high temperature such as 1000° C. for 1000 hours has been indispensable after the firing. In contrast, since the ceramic within the scope of the present disclosure requires no long-time heat treatment, the productivity is significantly improved, and furthermore, the ceramic can be fired at 1250° C. or lower, thus allowing a furnace body, a setter, a sagger, and the like to be significantly kept from being worn during the production.

In an aspect, the ranges of x and y satisfy:
x, y≤0.1 and 0≤x+y≤0.12 when 0≤x, y;
−0.1≤x<0 and 0≤y≤0.1 when 0>x and 0≤y;
−0.1≤x, y and −0.12≤x+y<0 when 0≥x and 0>y; and
0<x≤0.1 and −0.1≤y<0 when 0<x and 0>y.

In an aspect, the ranges of x and y satisfy:
x, y≤0.1 and 0≤x+y≤0.11 when 0≤x, y;
−0.1≤x<0 and 0≤y≤0.1 when 0>x and 0≤y;
−0.1≤x, y and −0.11≤x+y<0 when 0≥x and 0>y; and
0<x≤0.1 and −0.1≤y<0 when 0<x and 0>y.

In an aspect, the ranges of x and y satisfy:
0≤x+y≤0.1 when 0≤x, y;
−0.1≤x<0 and 0≤y≤0.1 when 0>x and 0≤y;
−0.1≤x+y<0 when 0≥x and 0>y; and
0<x≤0.1 and −0.1≤y<0 when 0<x and 0>y.

In an aspect, the ranges of x and y satisfy:
0≤x+y≤0.08 when 0≤x, y;
−0.08≤x<0 and 0≤y≤0.08 when 0>x and 0≤y;
−0.08≤x+y<0 when 0≥x and 0>y; and
0<x≤0.08 and −0.08≤y<0 when 0<x and 0>y.

In an aspect, the ranges of x and y satisfy:
0≤x≤0.05 and 0≤y≤0.05 when 0≤x, y;
−0.05≤x<0 and 0≤y≤0.05 when 0>x and 0≤y;
−0.05≤x<0 and −0.05≤y<0 when 0≥x and 0>y; and
0<x≤0.05 and −0.05≤y<0 when 0<x and 0>y.

In an aspect, the ranges of x and y satisfy:
0≤x+y=0.05 when 0≤x, y;
−0.05≤x<0 and 0≤y≤0.05 when 0>x and 0≤y;
−0.05≤x+y<0 when 0≥x and 0>y; and
0<x≤0.05 and −0.05≤y<0 when 0<x and 0>y.

In an aspect, the ranges of x and y may be ranges determined by arbitrarily combining the above-mentioned ranges of x and y in “when 0≤x, y”, “when 0>x and 0≤y”, “when 0≥x and 0>y”, and “when 0<x and 0>y”.

In a preferred aspect, x and y are 0. More specifically, the formula represented by (1-m)PbSc_{0.5-x}Ta_{0.5+x}O₃-mPbMg_{0.5-y}W_{0.5+y}O₃ is determined to be (1-m)PbSc_{0.5}Ta_{0.5}P₃-mPbMg_{0.5}W_{0.5}O₃.

From the viewpoint of improving the electrocaloric effect at a low temperature, the range of m is preferably 0.05≤m≤0.5, more preferably 0.05≤m≤0.4, still more preferably 0.05≤m≤0.3.

The crystal structure of the ceramic according to an embodiment of the present disclosure may be a perovskite structure. The ceramic that has a perovskite structure is meant to encompass not only a ceramic that has a “perovskite-type crystal structure”, but also a ceramic that has a “similar perovskite-type crystal structure”. For example, the ceramic that has a perovskite structure may have a crystal structure that can be recognized as a crystal structure of perovskite by those skilled in the art of ceramics in X-ray diffraction.

### [Electrocaloric Effect Element]

The electrocaloric effect element according to the present disclosure has a stacked body in which an electrode layer and a ceramic layer containing the ceramic according to the present disclosure as a main component are alternately stacked.

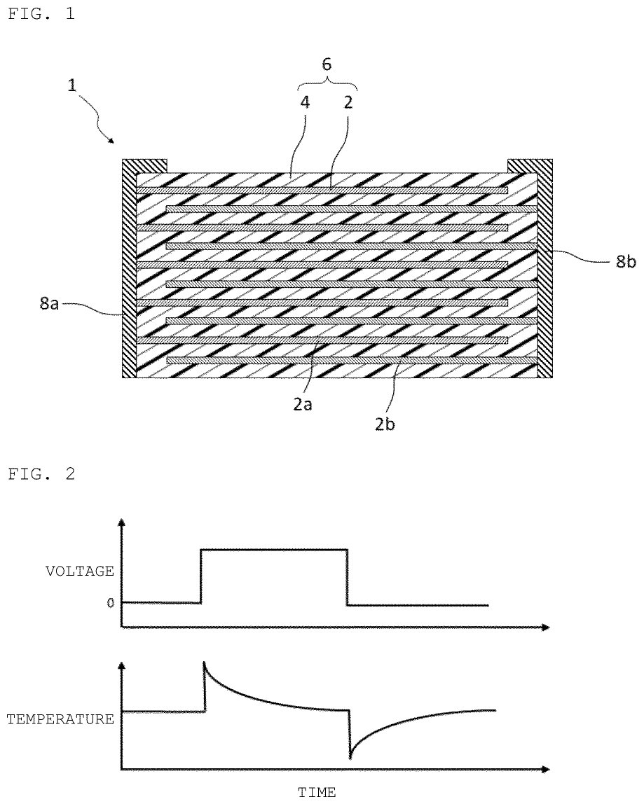

As shown in FIG. 1, an electrocaloric effect element 1 according to an embodiment of the present disclosure includes a stacked body 6 in which electrode layers 2a and 2b (hereinafter, also referred to collectively as “electrode layers 2”) and a ceramic layers 4 are alternately stacked, and external electrodes 8a and 8b (hereinafter, also referred to collectively as “external electrodes 8”) connected to the electrode layers 2. The electrode layers 2a and 2b are electrically connected respectively to the external electrodes 8a and 8b disposed on end surfaces of the stacked body 6. When a voltage is applied from the external electrodes 8a and 8b, an electric field is formed between the electrode layers 2a and 2b. This electric field causes the ceramic layers 4 to generate heat due to an electrocaloric effect. When the voltage is removed, the electric field disappears, and as a result, the ceramic layers 4 absorb heat due to the electrocaloric effect.

The electrode layers 2 is so-called internal electrodes. The electrode layers 2 can have a function of transferring a heat quantity between the ceramic layers 4 and the outside, in addition to the function of applying the electric field to the ceramic layers 4.

The electrode layers mentioned above may be electrode layers that have a main component composed of a noble metal. In this regard, the “main component” in the electrode layer means that the electrode layer is composed of 80% by mass or more of noble metal, and for example, means that the noble metal is 95% by mass or more, more preferably 98% by mass or more, still preferably 99% or more, still more preferably 99.5% by mass or more, particularly preferably 99.9% by mass or more of the electrode layer.

In the present specification, the “noble metal” may be, for example, Au, Ag, Pt, or Pd. From the viewpoint of improving the electrocaloric effect at a low temperature, the main component of the electrode layers for use in the present disclosure may be Pt or Pd. More specifically, the electrode layers may be electrode layers of Pt or Pd. However, from the viewpoint of improvement in chemical durability and/or cost, the noble-metal electrode layer may be an alloy or mixture of Pt and/or Pd and another element (for example, Ag, Pd, Rh, Au, or the like). For example, the alloy may be an Ag—Pd alloy. Also when the electrode layers of Pt or Pd are composed of the alloy or mixture thereof, a similar effect can be obtained. In addition, the electrode layers may contain other elements, which can be mixed as impurities, particularly inevitable elements (for example, Fe, Al₂O₃, and the like). Also in this case, similar effects can be obtained.

The thickness of the electrode layer 2 can be preferably 0.2 μm to 10 μm, more preferably 1.0 μm to 5.0 μm, for example, 2.0 μm to 5.0 μm, or 2.0 μm to 4.0 μm. When the thickness of the electrode layer is 0.5 μm or more, the resistance of the electrode layer can be reduced, and heat transport efficiency can be increased. In addition, when the thickness of the electrode layer is 10 μm or less, the thickness (thus, volume) of the ceramic layer can be increased, and the heat quality that can be handled by the electrocaloric effect of the whole element can be further increased. In addition, the element can be made smaller.

The ceramic layer 4 may contain, as a main component, one type of ceramic or two or more types of ceramics.

In this regard, the “main component” in the ceramic layer means that the ceramic layer is substantially composed of a target ceramic, and for example, means that the target ceramic is 90% by mass or more, more preferably 95% or more, still preferably 98% by mass or more, still more preferably 99% by mass or more, particularly preferably 99.5% by mass or more of the ceramic layer. The other component can be a crystal phase that has a structure different from the perovskite structure, referred to as a pyrochlore structure, other elements mixed as impurities, and particularly inevitable elements (for example, Zr, C, and the like).

The composition of the ceramic layer 4 can be determined by high-frequency inductively coupled plasma optical emission spectroscopy, X-ray fluorescence spectroscopy, or another method. In addition, the structure of the ceramic layer 4 can be determined by powder X-ray diffraction.

The thickness of the ceramic layer 4 can be preferably 5 μm to 100 μm, more preferably 5 μm to 50 μm, still preferably 10 μm to 50 μm, still more preferably 20 μm to 50 μm, particularly preferably 20 μm to 40 μm. Further increasing the thickness of the ceramic layer can increase the heat quality that can be handled by the element. Further reducing the thickness of the ceramic layer can achieve a higher ΔT. In addition, the withstand voltage can also be improved.

The withstand voltage of the ceramic layer 4 can be preferably 15 MV/m or more, more preferably 20 MV/m or more, still preferably 25 MV/m or more. Further increasing the withstand voltage of the ceramic layer allows a higher voltage (electric field) to be applied, thereby allowing larger ΔT to be obtained.

The material constituting the pair of the external electrodes 8a and 8b is not particularly limited, examples thereof include Ag, Cu, Pt, Ni, Al, Pd, and Au, and alloys thereof (for example, Ag—Pd and the like), and electrodes composed of the metals and glass or electrodes composed of the metals and resin may be employed. Among the metals, Ag is preferable.

While the electrode layers 2 and the ceramic layers 4 are alternately stacked in the electrocaloric effect element 1, the numbers of electrode layers and ceramic layers stacked are not particularly limited in the electrocaloric effect element according to the present disclosure. In addition, all of the internal electrodes do not have to be connected to the external electrodes, and the element may include internal electrodes that are not connected to the external electrodes as necessary for heat transfer, stress relaxation due to piezoelectricity or electrostriction, and the like.

While the internal electrodes and the ceramic layers have contact with each other substantially over the whole surface in the electrocaloric effect element 1, the electrocaloric effect element according to the present disclosure is not limited to such a structure, and is not particularly limited as long as the element has a structure in which a voltage (electric field) can be applied to the ceramic layers. In addition, while the electrocaloric effect element 1 has a rectangular parallelepiped block shape, the shape of the electrocaloric effect element according to the present disclosure is not limited thereto, and for example, the electrocaloric effect element may have a cylindrical shape or a sheet shape, and may further have irregularities, through holes, and the like. In addition, the internal electrodes may be exposed at the surface for heat transfer or heat exchange with the outside.

The above-mentioned ceramic and electrocaloric effect element according to the present embodiment are manufactured, for example, in the following manner.

As raw materials, high-purity lead oxide (Pb₃O₄), tantalum oxide (Ta₂O₅), scandium oxide (Sc₂O₃), magnesium carbonate (MgCO₃), and tungsten oxide (WO₃) are weighed so as to have desired composition ratio after firing. The above raw materials are subjected to grinding and mixing with partially stabilized zirconia (PSZ) balls, pure water, a dispersant, and the like with the use of a ball mill. Thereafter, the ground and mixed slurry is dried and sized, and then subjected to calcination under the conditions of, for example, 800° C. to 900° C. in the air. The calcined powder obtained is mixed with PSZ balls, ethanol, toluene, a dispersant, and the like, and subjected to grinding. Then, a dissolved binder solution is added to the ground powder obtained, and mixed therewith to prepare a slurry for sheet molding. The prepared slurry is formed into a sheet shape on a support, and printing with a Pt electrode paste is performed thereon. The printed sheets and unprinted sheets are stacked so as to have a desired structure, then subjected to pressure bonding at a pressure of 100 MPa to 200 MPa, and cut to prepare a green chip. The green chip is subjected to a heat treatment at 500° C. to 600° C. in the air to perform a binder removal treatment. Then, the chip subjected to the binder removal is subjected to firing at 1000° C. to 1500° C. together with a PbZrO₃ powder for creating a Pb atmosphere with the use of, for example, an alumina sealed sagger. Thereafter, end surfaces of the chip are polished with sandpaper, and an external electrode paste is applied thereto, and subjected to a baking treatment at a predetermined temperature, thereby allowing such an electrocaloric effect element as shown in FIG. 1 to be obtained.

The electrocaloric effect element according to the present disclosure exhibits an excellent electrocaloric effect, and thus, can be used as a thermal management element, particularly as a cooling element (including an air conditioning apparatus such as an air conditioner, a refrigerator, and a cooling/heat pump element of a freezer).

The present disclosure also provides an electronic component including the electrocaloric effect element according to the present disclosure, and an electronic device including the electrocaloric effect element or electronic component according to the present disclosure.

The electronic component is not particularly limited, and examples thereof include an electronic component for use in an air conditioner, a refrigerator, or a freezer; an electronic component (for example, a battery) for use in air conditioning for an electric vehicle or a hybrid car; and a component commonly used in an electronic device such as: an integrated circuit (IC) such as a central processing unit (CPU), a hard disk (HDD), a power management IC (PMIC), a power amplifier (PA), a transceiver IC, and a voltage regulator (VR); a light-emitting element such as a light-emitting diode (LED), an incandescent light bulb, and a semiconductor laser; a component that can serve as a heat source, such as a field-effect transistor (FET); and other components, for example, a lithium ion battery, a substrate, a heat sink, a housing, and the like.

The electronic device is not particularly limited, and examples thereof include an air conditioner, a refrigerator, and a freezer; an air conditioner for use as a heat pump, and an air conditioner for an electric vehicle or a hybrid car; and a small electronic device such as a cellular phone, a smartphone, a personal computer (PC), a tablet terminal, a hard disc drive, and a data server.

The electric heat element according to the present disclosure can be used as a thermal management system (or a temperature management system) that manages heat (temperature) of the electronic component and the electronic device. Examples of the thermal management system include a cooling system that cools the electronic component and the electronic device.

### Examples

### <Fabrication of Electrocaloric Effect Element>

High-purity lead oxide (Pb₃O₄), tantalum oxide (Ta₂O₅), scandium oxide (Sc₂O₃), magnesium carbonate (MgCO₃), and tungsten oxide (WO₃) were prepared as raw materials. These raw materials were weighed so as to have predetermined composition ratios as shown in Tables 1 to 4 after firing, and subjected to grinding and mixing with partially stabilized zirconia (PSZ) balls of 2 mm in diameter, pure water, and a dispersant for 16 hours with the use of a ball mill. Thereafter, the ground and mixed slurry was dried on a hot plate and sized, and then subjected to calcination for 2 hours under the condition of 850° C. in the air.

The calcined powder obtained was mixed with PSZ balls of 5 mm in diameter, ethanol, toluene, and a dispersant for 16 hours, and subjected to grinding. Next, a dissolved binder solution was added to the ground powder obtained, and mixed for 4 hours to prepare a slurry for sheet molding. The prepared slurry was formed into a sheet shape on a pet film by a doctor blade method to have a thickness corresponding to the thickness of a predetermined ceramic layer, cut into strips, and then subjected to screen printing with a platinum internal electrode paste. It is to be noted that the sheet thickness of a stacked element to be fabricated was controlled by changing the gap of a doctor blade for use in sheet molding.

Predetermined numbers of sheets subjected to the printing with the platinum internal electrode paste and unprinted sheets were stacked, then subjected to pressure bonding at a pressure of 150 MPa, and cut to prepare a green chip. The green chip was subjected to a heat treatment at 550° C. for 24 hours in the air to perform a binder removal treatment. Next, the green chip was sealed in an alumina sealed sagger together with a PbZrO₃ powder for creating a Pb atmosphere, and subjected to firing at 1150 to 1400° C. for 4 hours. The sample of sample number 1 as a comparative example, listed in Table 1, was subjected to firing at a high temperature of 1400° C., and then a heat treatment at 1000° C. for 1000 hours.

Thereafter, the end surfaces of the chip was polished with sandpaper, and an Ag external electrode paste was applied thereto, and subjected to a baking treatment at a temperature of 750° C., thereby providing such an electrocaloric effect element as shown in FIG. 1.

The size of the element obtained was about L 10.2 mm×W 7.2 mm×T 0.88 mm for the element in which the thickness of the ceramic layer was 40 μm. In addition, the number of ceramic layers sandwiched between the internal electrode layers was 19, the electrode area was 49 mm²/layer, and the total electrode area was 49 mm²×19 layers. It is to be noted that the thickness of the ceramic layer of the element obtained as mentioned above was confirmed with the use of a scanning electron microscope after polishing a cross section of the element.

### <Evaluation>

### (Composition)

The ceramic composition of the obtained element was confirmed with the use of high-frequency inductively coupled plasma optical emission spectroscopy and X-ray fluorescence spectroscopy.

### (Crystal Structure)

For evaluating the crystal structure of the obtained element, powder X-ray diffraction measurement was performed. One element was randomly selected from each lot, ground in a mortar, and then subjected to the measurement to acquire an X-ray diffraction profile. From the obtained X-ray diffraction profile, whether the crystal structure of the ceramic was the perovskite structure was confirmed, and the presence or absence and existence ratio of an impurity phase (mainly a pyrochlore phase) were estimated from the intensity ratio. When the existence ratio of the perovskite structure was 0.95 or more, the main component was determined to have a perovskite structure, and when the existence ratio was less than 0.95, a different phase was determined to be present.

### (Electrocaloric Effect)

While an ultrafine K thermocouple of 50 μm in diameter was attached to a central part of the element surface with a Kapton tape to constantly monitor the temperature, a wire for voltage application was bonded to both ends of the external electrodes with an Ag paste, and a voltage was applied with the use of a high voltage generator.

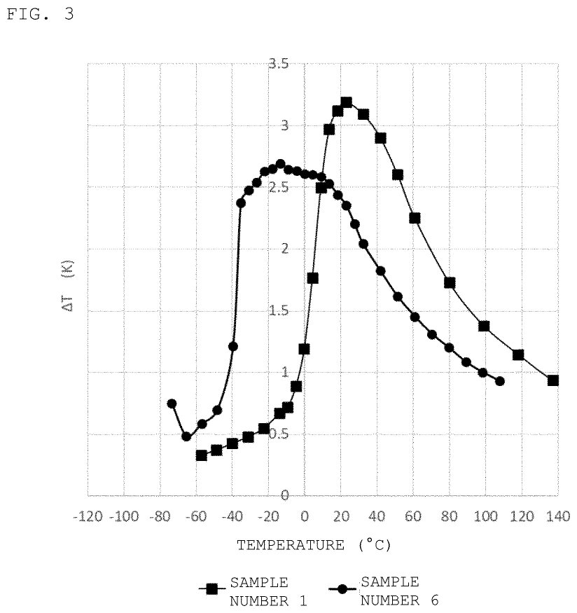

The electrocaloric effect was evaluated by applying a voltage to the sample in accordance with such a sequence as shown in the upper graph of FIG. 2. More specifically, first, the voltage was applied to the sample, the voltage was kept as it was, then, the applied voltage was removed, and kept as it was, and this operation was repeated to measure a change in electrocaloric effect. When the voltage is applied in accordance with such a sequence, the sample temperature is increased at the same time as the application in the step of applying the voltage, the heat is gradually diffused to decrease the sample temperature to the same temperature as that before the voltage application in the step of maintaining the applied state, the sample temperature is decreased at the same time as the removal in the step of removing the applied voltage, and the sample temperature is increased to the original temperature in the step of maintaining the non-applied state. This is derived from the fact that the ferroelectric domains are aligned or disordered by the application and removal of the voltage, and such endothermic and exothermic effects (electrocaloric effect) is obtained by changes in entropy. The adiabatic temperature change ΔT is determined from a temperature change in the application and removal of the voltage as described above. Specifically, in the present example, after applying the voltage of 15 MV/m, the temperature was measured with the voltage kept applied for 50 seconds, and then after removing the voltage, the temperature was measured without any voltage applied for 50 seconds. This sequence was repeated three times. During the sequence of voltage application and voltage removal, the temperature of the element was constantly measured, and the adiabatic temperature change ΔT was determined from the temperature change. In addition, the samples in which the absolute values of the adiabatic temperature changes ΔT at −10° C. and 0° C. were each 1.5 K or more were regarded as Go determinations. The results are shown in Tables 1 to 4.

The results of the evaluation mentioned above are shown below. It is to be noted that samples marked with “*” in the tables are comparative examples, whereas the other samples are examples.

TABLE 1

| | | | | | Adiabatic | | |
|---|---|---|---|---|---|---|---|
| | | | | | Temperature | | |
| | | Composition | | | Change | | |
| Sample | | (1 − m)PbSc_{0.5-x}Ta_{0.5+x}O₃—mPbMg_{0.5-y}W_{0.5+y}O₃ | | | ΔT(K) | | |
| Number | | m | x | y | 0° C. | −10° C. | Crystal Structure |
| * | 1 | 0 | 0 | 0 | 1.2 | 0.7 | perovskite structure |
| * | 2 | 0.01 | 0 | 0 | 0.9 | 0.3 | perovskite structure |
| | 3 | 0.03 | 0 | 0 | 1.5 | 1.5 | perovskite structure |
| | 4 | 0.05 | 0 | 0 | 2.2 | 2 | perovskite structure |
| | 5 | 0.1 | 0 | 0 | 2.6 | 2.6 | perovskite structure |
| | 6 | 0.2 | 0 | 0 | 2.5 | 2.6 | perovskite structure |
| | 7 | 0.5 | 0 | 0 | 2 | 2.5 | perovskite structure |
| | 8 | 0.6 | 0 | 0 | 1.5 | 1.5 | perovskite structure |
| * | 9 | 0.7 | 0 | 0 | 0.8 | 2.5 | perovskite structure |

TABLE 2

| | | | | | Adiabatic | | |
|---|---|---|---|---|---|---|---|
| | | | | | Temperature | | |
| | | | | | Change | | |
| Sample | | (1 − m)PbSc_{0.5-x}Ta_{0.5+x}O₃—mPbMg_{0.5-y}W_{0.5+y}O₃ | | | ΔT(K) | | |
| Number | | m | x | y | 0° C. | −10° C. | Crystal Structure |
| | 10 | 0.03 | 0 | 0 | 1.5 | 1.5 | perovskite structure |
| | 11 | 0.03 | 0.05 | 0.05 | 1.5 | 1.6 | perovskite structure |
| * | 12 | 0.03 | 0.08 | 0.08 | — | — | a large number of |
| | | | | | | | different phases |
| * | 13 | 0.03 | 0.1 | 0.1 | 0.9 | electrostatic | a large number of |
| | | | | | | discharge | different phases |
| | | | | | | caused | |
| | 14 | 0.03 | 0.05 | −0.05 | 1.6 | 1.5 | perovskite structure |
| | 15 | 0.03 | 0.08 | −0.08 | 1.5 | 1.6 | perovskite structure |
| | 16 | 0.03 | 0.1 | −0.1 | 1.8 | 1.5 | perovskite structure |
| * | 17 | 0.03 | 0.1 | −0.11 | — | — | a large number of |
| | | | | | | | different phases |
| * | 18 | 0.03 | 0.11 | −0.1 | — | — | a large number of |
| | | | | | | | different phases |
| | 19 | 0.03 | −0.05 | −0.05 | 1.6 | 1.6 | perovskite structure |
| * | 20 | 0.03 | −0.08 | −0.08 | — | — | a large number of |
| | | | | | | | different phases |
| * | 21 | 0.03 | −0.1 | −0.1 | — | — | a large number of |
| | | | | | | | different phases |
| | 22 | 0.03 | −0.05 | 0.05 | 1.7 | 1.6 | perovskite structure |
| | 23 | 0.03 | −0.08 | 0.08 | 1.5 | 1.5 | perovskite structure |
| | 24 | 0.03 | −0.1 | 0.1 | 1.6 | 1.5 | perovskite structure |
| * | 25 | 0.03 | −0.1 | 0.11 | — | — | a large number of |
| | | | | | | | different phases |
| * | 26 | 0.03 | −0.11 | 0.1 | — | — | a large number of |
| | | | | | | | different phases |
| | 27 | 0.03 | 0 | 0.05 | 1.6 | 1.7 | perovskite structure |
| | 28 | 0.03 | 0 | 0.08 | 1.5 | 1.8 | perovskite structure |
| | 29 | 0.03 | 0 | 0.1 | 1.6 | 1.5 | perovskite structure |
| * | 30 | 0.03 | 0 | 0.11 | — | — | a large number of |
| | | | | | | | different phases |
| | 31 | 0.03 | 0.05 | 0 | 1.8 | 1.8 | perovskite structure |
| | 32 | 0.03 | 0.08 | 0 | 1.5 | 1.6 | perovskite structure |
| | 33 | 0.03 | 0.1 | 0 | 1.6 | 1.5 | perovskite structure |
| * | 34 | 0.03 | 0.11 | 0 | — | — | a large number of |
| | | | | | | | different phases |
| | 35 | 0.03 | 0 | −0.05 | 1.5 | 1.5 | perovskite structure |
| | 36 | 0.03 | 0 | −0.08 | 1.7 | 1.6 | perovskite structure |
| | 37 | 0.03 | 0 | −0.1 | 1.6 | 1.5 | perovskite structure |
| * | 38 | 0.03 | 0 | −0.11 | — | — | a large number of |
| | | | | | | | different phases |
| | 39 | 0.03 | −0.05 | 0 | 1.5 | 1.6 | perovskite structure |
| | 40 | 0.03 | −0.08 | 0 | 1.7 | 1.6 | perovskite structure |
| | 41 | 0.03 | −0.1 | 0 | 1.5 | 1.5 | perovskite structure |
| * | 42 | 0.03 | −0.11 | 0 | — | — | a large number of |
| | | | | | | | different phases |

TABLE 3

| | | | | | Adiabatic | | |
|---|---|---|---|---|---|---|---|
| | | | | | Temperature | | |
| | | | | | Change | | |
| Sample | | (1 − m)PbSc_{0.5-x}Ta_{0.5+x}O₃—mPbMg_{0.5-y}W_{0.5+y}O₃ | | | ΔT(K) | | |
| Number | | m | x | y | 0° C. | −10° C. | Crystal Structure |
| | 43 | 0.2 | 0 | 0 | 2.5 | 2.6 | perovskite structure |
| | 44 | 0.2 | 0.05 | 0.05 | 2.5 | 2.5 | perovskite structure |
| * | 45 | 0.2 | 0.08 | 0.08 | — | — | a large number of |
| | | | | | | | different phases |
| * | 46 | 0.2 | 0.1 | 0.1 | 0.9 | electrostatic | a large number of |
| | | | | | | discharge | different phases |
| | | | | | | caused | |
| | 47 | 0.2 | 0.05 | −0.05 | 2.3 | 2.5 | perovskite structure |
| | 48 | 0.2 | 0.08 | −0.08 | 2.5 | 2.6 | perovskite structure |
| | 49 | 0.2 | 0.1 | −0.1 | 2.5 | 2.4 | perovskite structure |
| * | 50 | 0.2 | 0.1 | −0.11 | — | — | a large number of |
| | | | | | | | different phases |
| * | 51 | 0.2 | 0.11 | −0.1 | — | — | a large number of |
| | | | | | | | different phases |
| | 52 | 0.2 | −0.05 | −0.05 | 2.5 | 2.6 | perovskite structure |
| * | 53 | 0.2 | −0.08 | −0.08 | — | — | a large number of |
| | | | | | | | different phases |
| * | 54 | 0.2 | −0.1 | −0.1 | — | — | a large number of |
| | | | | | | | different phases |
| | 55 | 0.2 | −0.05 | 0.05 | 2.6 | 2.6 | perovskite structure |
| | 56 | 0.2 | −0.08 | 0.08 | 2.7 | 2.6 | perovskite structure |
| | 57 | 0.2 | −0.1 | 0.1 | 2.5 | 2.5 | perovskite structure |
| * | 58 | 0.2 | −0.1 | 0.11 | — | — | a large number of |
| | | | | | | | different phases |
| * | 59 | 0.2 | −0.11 | 0.1 | — | — | a large number of |
| | | | | | | | different phases |
| | 60 | 0.2 | 0 | 0.05 | 2.5 | 2.8 | perovskite structure |
| | 61 | 0.2 | 0 | 0.08 | 2.6 | 2.5 | perovskite structure |
| | 62 | 0.2 | 0 | 0.1 | 2.4 | 2.3 | perovskite structure |
| * | 63 | 0.2 | 0 | 0.11 | — | — | a large number of |
| | | | | | | | different phases |
| | 64 | 0.2 | 0.05 | 0 | 2.5 | 2.5 | perovskite structure |
| | 65 | 0.2 | 0.08 | 0 | 2.6 | 2.4 | perovskite structure |
| | 66 | 0.2 | 0.1 | 0 | 2.6 | 2.6 | perovskite structure |
| * | 67 | 0.2 | 0.11 | 0 | — | — | a large number of |
| | | | | | | | different phases |
| | 68 | 0.2 | 0 | −0.05 | 2.6 | 2.6 | perovskite structure |
| | 69 | 0.2 | 0 | −0.08 | 2.5 | 2.5 | perovskite structure |
| | 70 | 0.2 | 0 | −0.1 | 2.6 | 2.4 | perovskite structure |
| * | 71 | 0.2 | 0 | −0.11 | — | — | a large number of |
| | | | | | | | different phases |
| | 72 | 0.2 | −0.05 | 0 | 2.4 | 2.6 | perovskite structure |
| | 73 | 0.2 | −0.08 | 0 | 2.5 | 2.4 | perovskite structure |
| | 74 | 0.2 | −0.1 | 0 | 2.5 | 2.6 | perovskite structure |
| * | 75 | 0.2 | −0.11 | 0 | — | — | a large number of |
| | | | | | | | different phases |

TABLE 4

| | | | | | Adiabatic | | |
|---|---|---|---|---|---|---|---|
| | | | | | Temperature | | |
| | | | | | Change | | |
| Sample | | (1 − m)PbSc_{0.5-x}Ta_{0.5+x}O₃—mPbMg_{0.5-y}W_{0.5+y}O₃ | | | ΔT(K) | | |
| Number | | m | x | y | 0° C. | −10° C. | Crystal Structure |
| | 76 | 0.6 | 0 | 0 | 1.5 | 1.5 | perovskite structure |
| | 77 | 0.6 | 0.05 | 0.05 | 1.5 | 1.5 | perovskite structure |
| * | 78 | 0.6 | 0.08 | 0.08 | — | — | a large number of |
| | | | | | | | different phases |
| * | 79 | 0.6 | 0.1 | 0.1 | 0.8 | 0.8 | perovskite structure |
| | 80 | 0.6 | 0.05 | −0.05 | 1.6 | 1.5 | perovskite structure |
| | 81 | 0.6 | 0.08 | −0.08 | 1.5 | 1.8 | perovskite structure |
| | 82 | 0.6 | 0.1 | −0.1 | 1.9 | 1.5 | perovskite structure |
| * | 83 | 0.6 | 0.1 | −0.11 | — | — | a large number of |
| | | | | | | | different phases |
| * | 84 | 0.6 | 0.11 | −0.1 | — | — | a large number of |
| | | | | | | | different phases |
| | 85 | 0.6 | −0.05 | −0.05 | 1.5 | 1.8 | perovskite structure |
| * | 86 | 0.6 | −0.08 | −0.08 | — | — | a large number of |
| | | | | | | | different phases |
| * | 87 | 0.6 | −0.1 | −0.1 | — | — | a large number of |
| | | | | | | | different phases |
| | 88 | 0.6 | −0.05 | 0.05 | 1.5 | 1.6 | perovskite structure |
| | 89 | 0.6 | −0.08 | 0.08 | 1.6 | 1.7 | perovskite structure |
| | 90 | 0.6 | −0.1 | 0.1 | 1.8 | 1.6 | perovskite structure |
| * | 91 | 0.6 | −0.1 | 0.11 | — | — | a large number of |
| | | | | | | | different phases |
| * | 92 | 0.6 | −0.11 | 0.1 | — | — | a large number of |
| | | | | | | | different phases |
| | 93 | 0.6 | 0 | 0.05 | 1.7 | 1.6 | perovskite structure |
| | 94 | 0.6 | 0 | 0.08 | 1.7 | 1.7 | perovskite structure |
| | 95 | 0.6 | 0 | 0.1 | 1.6 | 1.7 | perovskite structure |
| * | 96 | 0.6 | 0 | 0.11 | — | — | a large number of |
| | | | | | | | different phases |
| | 97 | 0.6 | 0.05 | 0 | 1.6 | 1.6 | perovskite structure |
| | 98 | 0.6 | 0.08 | 0 | 1.7 | 1.5 | perovskite structure |
| | 99 | 0.6 | 0.1 | 0 | 1.5 | 1.6 | perovskite structure |
| * | 100 | 0.6 | 0.11 | 0 | — | — | a large number of |
| | | | | | | | different phases |
| | 101 | 0.6 | 0 | −0.05 | 1.6 | 1.7 | perovskite structure |
| | 102 | 0.6 | 0 | −0.08 | 1.8 | 1.8 | perovskite structure |
| | 103 | 0.6 | 0 | −0.1 | 1.5 | 1.6 | perovskite structure |
| * | 104 | 0.6 | 0 | −0.11 | — | — | a large number of |
| | | | | | | | different phases |
| | 105 | 0.6 | −0.05 | 0 | 1.6 | 1.5 | perovskite structure |
| | 106 | 0.6 | −0.08 | 0 | 1.7 | 1.6 | perovskite structure |
| | 107 | 0.6 | −0.1 | 0 | 1.6 | 1.8 | perovskite structure |
| * | 108 | 0.6 | −0.11 | 0 | — | — | a large number of |
| | | | | | | | different phases |

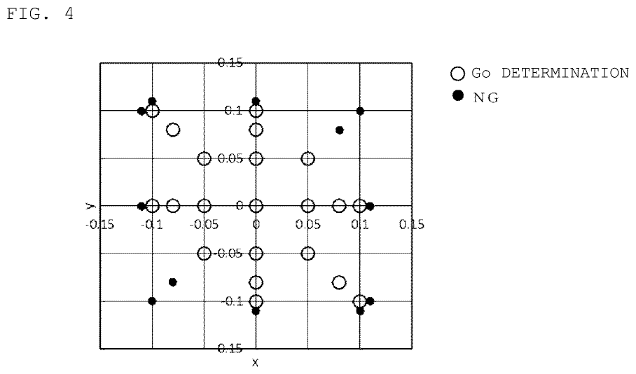

Tables 1 to 4 show the results of the electrocaloric effects of the samples fabricate. Specifically, Table 1 shows the electrocaloric effects of the samples with the values of x and y in formula (1) being fixed to 0 and m changed to various values. Tables 2 to 4 show the electrocaloric effects of the samples with x and y changed to various values in the case of the formula (1) respectively with m=0.03, m=0.2, and m=0.6. It is to be noted that Tables 1 to 4 show the respective electrocaloric effects in the cases of the sample temperatures of 0° C. and −10° C. In addition, representatively, FIG. 3 shows the temperature dependence of the electrocaloric effect for the conventionally known sample of sample number 1 and the sample of sample number 6 according to the present disclosure. Further, as a result of the XRD measurement, the samples with the compositions shown in Table 1 all contained a main component including a desired perovskite structure, with small numbers of different phases.

As shown in FIG. 3, it has been confirmed that the sample of sample number 1 with the composition of PbSc_{0.5}Ta_{0.5}O₃, which is a conventional PST ceramic, has an adiabatic temperature change of 1.5 K or more in the temperature range of 20° C. or higher, and exhibits an excellent electrocaloric effect. The sample of sample number 1 is suitable for driving at room temperature or higher. However, as shown in Table 1, it has been confirmed that the sample of sample number 1 has adiabatic temperature changes smaller than 1.5 K at 0° C. and −10° C., and electrocaloric effects significantly decreased at the low temperatures.

As shown in Table 1, the samples of sample numbers 3 to 8 with the compositions within the scope of the present disclosure exhibited adiabatic temperature changes more than 1.5 K at 0° C. and −10° C. In particular, as shown in FIG. 3, it has been confirmed that the sample of sample number 6 has an excellent adiabatic temperature change of 2 K or more in the wide temperature range from 20° C. to −40° C. The sample of sample number 2 with the value of m outside the scope of the present disclosure achieved an excellent electrocaloric effect at 0° C. or higher, but poor electrocaloric effects at 0° C. and −10° C., which were 0.9 K and 0.3 K. This is considered to be because the small value of m results in the insufficiently decreased ferroelectric transition temperature of the ceramic. The sample number 9 with the value of m outside the scope of the present disclosure achieved a poor electrocaloric effect at 0° C., which was 0.8 K. This is considered to be caused by the fact that the value of m was large, thus excessively lowering the ferroelectric transition temperature of the ceramic and decreasing the ferroelectricity.

Tables 2, 3, and 4 respectively show the measurement results of the electrocaloric effects of the ceramics represented by the formula (1) in the cases of m=0.03, m=0.2, and m=0.6. The samples with m within the scope of the present disclosure was successfully obtained such that the most stable material with both x and y around 0 including a desired crystal structure was close to 100% in percentage. Also in the case where x and y both failed to be around 0, no different phase was produced, but when x and y were significantly deviated from 0, the percentage of the different phase was increased (see the columns of the crystal structures in Tables 2 to 4). The compositions within the scope of the present disclosure also achieved values of 1.5 K or more for the adiabatic temperature changes at 0° C. and −10° C.

FIG. 4 shows the composition ranges of x and y regarded as Go determinations in the result of the characteristic test in Table 2. From FIG. 4, it is determined that the ceramic within the scope of the present disclosure is regarded as a Go determination in the characteristic test. Tables 3 and 4 also show the same results as in FIG. 4.

The electrocaloric effect element according to the present disclosure can exhibit a highly electrocaloric effect, and can be thus used as a heat management element in, for example, an electric vehicle or a hybrid car, an air conditioner (for example, an air conditioner for use in an electric vehicle or a hybrid car, an air conditioner for use as a heat pump, and the like), a refrigerator, a freezer, or the like, and can be used as a cooling device for various electronic devices, for example, small electronic devices such as a mobile phone, a smartphone, a tablet terminal, a hard disk drive, and a data server that have a problem with countermeasures against heat, or personal computers (PCs).

### DESCRIPTION OF REFERENCE SYMBOLS

1: Electrocaloric effect element
2a, 2b: Electrode layer
4: Ceramic layer
6: Stacked body
8a, 8b: External electrode

1. A ceramic represented by:
(1-m)PbSc_{0.5-x}Ta_{0.5+x}O₃-mPbMg_{0.5-y}W_{0.5+y}O₃
wherein,
0.03≤m≤0.60,
x, y≤0.1 and 0≤x+y≤0.13 when 0≤x, y,
−0.1≤x<0 and 0≤y≤0.1 when 0>x and 0≤y,
−0.1≤x, y and −0.13≤x+y<0 when 0≥x and 0>y, and
0<x≤0.1 and −0.1≤y<0 when 0<x and 0>y.

2. The ceramic according to claim 1, wherein
0≤x+y≤0.1 when 0≤x, y, and
−0.1≤x+y<0 when 0≥x and 0>y.

3. The ceramic according to claim 2, wherein x is 0, and y is 0.

4. The ceramic according to claim 1, wherein x is 0, and y is 0.

5. The ceramic according to claim 1, wherein 0.05≤m≤0.5.

6. The ceramic according to claim 1, wherein:
x, y≤0.1 and 0≤x+y≤0.12 when 0≤x, y;
−0.1≤x<0 and 0≤y≤0.1 when 0>x and 0≤y;
−0.1≤x, y and −0.12≤x+y<0 when 0≥x and 0>y; and
0<x≤0.1 and −0.1≤y<0 when 0<x and 0>y.

7. The ceramic according to claim 1, wherein:
x, y≤0.1 and 0≤x+y≤0.11 when 0≤x, y;
−0.1≤x<0 and 0≤y≤0.1 when 0>x and 0=y;
−0.1≤x, y and −0.11≤x+y<0 when 0≥x and 0>y; and
0<x≤0.1 and −0.1≤y<0 when 0<x and 0>y.

8. The ceramic according to claim 1, wherein:
0≤x+y≤0.1 when 0≤x, y;
−0.1≤x<0 and 0≤y≤0.1 when 0>x and 0≤y;
−0.1≤x+y<0 when 0≥x and 0>y; and
0<x≤0.1 and −0.1≤y<0 when 0<x and 0>y.

9. The ceramic according to claim 1, wherein:
0≤x+y≤0.08 when 0≤x, y;
−0.08≤x<0 and 0≤y≤0.08 when 0>x and 0≤y;
−0.08≤x+y<0 when 0≥x and 0>y; and
0<x≤0.08 and −0.08≤y<0 when 0<x and 0>y.

10. The ceramic according to claim 1, wherein:
0≤x≤0.05 and 0≤y≤0.05 when 0≤x, y;
−0.05≤x<0 and 0≤y≤0.05 when 0>x and 0≤y;
−0.05≤x<0 and −0.05≤y<0 when 0≥x and 0>y; and
0<x=0.05 and −0.05≤y<0 when 0<x and 0>y.

11. The ceramic according to claim 1, wherein:
0≤x+y≤0.05 when 0≤x, y;
−0.05≤x<0 and 0≤y≤0.05 when 0>x and 0≤y;
−0.05≤x+y<0 when 0≥x and 0>y; and
0<x≤0.05 and −0.05≤y<0 when 0<x and 0>y.

12. The ceramic according to claim 1, wherein a crystal structure of the ceramic has a perovskite structure.

13. An electrocaloric effect element, wherein a noble metal electrode and the ceramic according to claim 1 are alternately stacked.

14. The electrocaloric effect element according to claim 13, wherein the noble metal electrode comprises Pt.

15. An electronic component comprising the electrocaloric effect element according to claim 13.

16. An electronic device comprising the electrocaloric effect element according to claim 13.

17. An electronic device comprising the electronic component according to claim 16.
